(19) United States
(12) Patent Application Publication
(10) Pub. No.: US 2004/0155326 A1
(43) Pub. Date: Aug. 12, 2004

(54) Semiconductor devices, and manufacturing methods, circuit substrates and electronic equipments for the same

(75) Inventor: Hatsuki Kanbayashi, Higashitagawagun (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/625,746

(22) Filed: Jul. 24, 2003

(30) Foreign Application Priority Data
Jul. 25, 2002 (JP) 2002-216661

(51) Int. Cl. H01L 23/02

(52) U.S. Cl. 257/686

(57) ABSTRACT

The invention provides semiconductor devices that are excellent in mountability. The invention also provides manufacturing methods, circuit substrates and electronic equipments for the same. A method of manufacturing a semiconductor device includes mounting a semiconductor chip having electrodes on a substrate having wiring patterns, and forming conductive layers that electrically connect the electrodes and the wiring patterns in a manner to pass side surfaces of the semiconductor chip.

### BACKGROUND OF THE INVENTION

1. Field of Invention

The present invention relates to semiconductor devices. The present invention also relates to manufacturing methods, circuit substrates and electronic equipments for the same.

2. Description of Related Art

In the related art, a so-called stacked type semiconductor device, in which a plurality of semiconductor chips are stacked in layers, has electrodes on the semiconductor chips or electrodes on the semiconductor chips and electrodes on a substrate that are electrically connected by wires.

However, in this case, since the wires are shaped in the form of loops, there are occasions where the thickness of the semiconductor device becomes large. Also, when numerous electrodes are present, there are occasions where the size of the semiconductor device becomes large.

### SUMMARY OF THE INVENTION

The present invention addresses or solves the above and/or other problems, and provides semiconductor devices that are excellent in mountability. The invention also provides manufacturing methods, circuit substrates and electronic equipments for the same.

A method of manufacturing a semiconductor device in accordance with the present invention includes: mounting a semiconductor chip having electrodes on a substrate having wiring patterns; and forming conductive layers that electrically connect the electrodes and the wiring patterns in a manner to pass side surfaces of the semiconductor chip.

In accordance with the present invention, the conductive layer is formed in a manner to pass a side surface of the semiconductor chip. For this reason, the size of the semiconductor device does not become large, and a semiconductor device with excellent mountability can be manufactured.

The method of manufacturing a semiconductor device may include face-up bonding the semiconductor chip.

A method of manufacturing a semiconductor device in accordance with the present invention includes: stacking in layers a plurality of semiconductor chips having electrodes on a substrate having wiring patterns; and forming a conductive layer that electrically connects the electrodes of any one of the semiconductor chips and the wiring patterns in a manner to pass a side surface of at least one of the semiconductor chips.

In accordance with the present invention, the conductive layer is formed in a manner to pass a side surface of the semiconductor chip. For this reason, even when multiple semiconductor chips are stacked in layers, the size of the semiconductor device does not become large, and a semiconductor device with excellent mountability can be manufactured.

The method of manufacturing a semiconductor device may include face-up bonding the plurality of semiconductor chips.

The method of manufacturing a semiconductor device may include mounting a second semiconductor chip, that is smaller than a first semiconductor chip among the plurality of semiconductor chips, on the first semiconductor chip.

The method of manufacturing a semiconductor device may further include forming a second conductive layer that electrically connects the electrodes of one of the semiconductor chips and the electrodes of another of the semiconductor chips in a manner to pass a side surface of at least one of the semiconductor chips.

The method of manufacturing a semiconductor device may further include face-down bonding a first semiconductor chip among the plurality of semiconductor chips to the substrate, and face-up bonding a second semiconductor chip to a side of the first semiconductor chip opposite to a side thereof where the electrodes are formed.

In the method of manufacturing a semiconductor device, the conductive layer may be formed by ejecting a solution containing fine-particles of conductive material.

By this, the conductive layer can be formed with a high density, such that a semiconductor device that is small in size and excellent in mountability can be manufactured.

A semiconductor device in accordance with the present invention includes: a substrate having wiring patterns; a plurality of stacked semiconductor chips having electrodes; a conductive layer that electrically connects the electrodes of any one of the semiconductor chips and the wiring patterns in a manner to pass a side surface of at least one of the semiconductor chips; and a second conductive layer that electrically connects the electrodes of one of the semiconductor chips and the electrodes of another of the semiconductor chips in a manner to pass a side surface of at least one of the semiconductor chips.

In accordance with the present invention, the conductive layer is formed in a manner to pass a side surface of the semiconductor chip. For this reason, even when multiple semiconductor chips are stacked in layers, the size of the semiconductor device does not become large, and a semiconductor device with excellent mountability can be provided.

In the semiconductor device, the plurality of semiconductor chips may be face-up bonded.

In the semiconductor device, a second semiconductor chip that is smaller than a first semiconductor chip among the plurality of semiconductor chips may be mounted on the first semiconductor chip.

In the semiconductor device, a first semiconductor chip among the plurality of semiconductor chips may be face-down bonded to the substrate, and a second semiconductor chip may be face-up bonded to a side of the first semiconductor chip opposite to a side thereof where the electrodes are formed.

A circuit substrate in accordance with the present invention has the semiconductor device described above mounted thereon.

An electronic equipment in accordance with the present invention has the semiconductor device described above.

### BRIEF DESCRIPTION OF THE DRAWINGS

FIG. 1 is a schematic that shows a method of manufacturing a semiconductor device in accordance with a first exemplary embodiment of the present invention;

FIG. 2 is a schematic that shows the method of manufacturing a semiconductor device in accordance with the first exemplary embodiment of the present invention;

FIG. 3 is a schematic that shows the method of manufacturing a semiconductor device in accordance with the first exemplary embodiment of the present invention;

FIG. 4 is a schematic that shows the method of manufacturing a semiconductor device in accordance with the first exemplary embodiment of the present invention;

FIG. 5 is a schematic that shows a method of manufacturing a semiconductor device in accordance with a second exemplary embodiment of the present invention;

FIG. 6 is a schematic that shows a circuit substrate in accordance with an exemplary embodiment of the present invention;

FIG. 7 is a schematic that shows an electronic apparatus in accordance with an exemplary embodiment of the present invention;

FIG. 8 is a schematic that shows an electronic apparatus in accordance with an exemplary embodiment of the present invention.

### DETAILED DESCRIPTION OF PREFERRED EMBODIMENTS

Hereunder, exemplary embodiments of the present invention are described with reference to the accompanying drawings. However, the present invention is not limited to the exemplary embodiments described below.

(First Exemplary Embodiment)

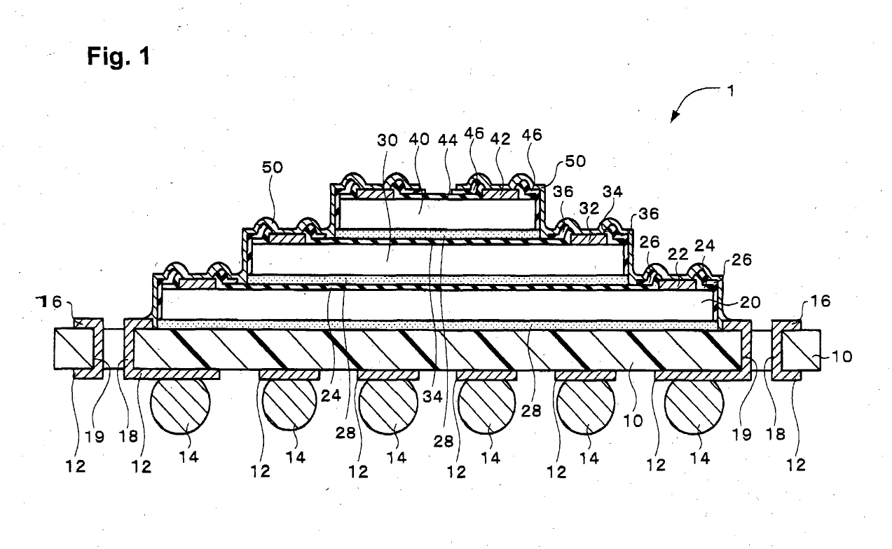

FIGS. 1-4 are schematics describing a method of manufacturing a semiconductor device in accordance with a first exemplary embodiment of the present invention.

Initially, a substrate 10 is prepared. The substrate 10 may also be referred to as a wiring substrate or an interposer. The shape of the substrate 10 in plan view is generally a rectangle, but is not limited to this specific shape. Also, the overall configuration of the substrate 10 is not particularly limited. Further, the thickness of the substrate 10 is not limited.

The material of the substrate 10 may be either organic or inorganic, and may be formed from a compound structure of these materials. As the substrate 10, a substrate or a film composed of, for example, polyethylene terephthalate (designated herein as PET) may be used. Alternatively, a flexible substrate composed of polyimide resin may be used as the substrate 10. A tape that is used in a FPC (Flexible Printed Circuit) technique or a TAB (Tape Automated Bonding) technique may be used as the flexible substrate. Also, as the substrate 10 that is composed of an inorganic material, for example, a ceramics substrate or a glass substrate may be used. As a compound structure of organic and inorganic materials, for example, a glass epoxy substrate may be used. Also, as the substrate 10, a multiple-layer substrate or a build-up type substrate may be used.

The substrate 10 may have wiring patterns 12. As shown in FIG. 1, the wiring patterns 12 may be formed only on a surface opposite to the side where semiconductor chips are mounted. However, without being limited to this, wiring patterns may be formed on both sides of the substrate 10. The wiring patterns 12 may be formed from a plurality of layers. For example, any of copper (Cu), chrome (Cr), titanium (Ti), nickel (Ni), and titanium-tungsten (Ti—W) layers may be stacked in layers to form the wiring patterns 12. The wiring patterns 12 may be formed by using a photolithography, sputter, or plating process. Also, a part of the wiring pattern 12 may be formed with a land section (not shown) having an area larger than a portion thereof that becomes to be a wiring. A dielectric film (not shown) may be formed on the surface of the wiring patterns 12 while avoiding portions that contact external terminals 14.

The substrate 10 may have through holes 19. Both of the surfaces of the substrate can be made electrically conductive through the through holes 19. For this, electrical connections to the wiring patterns 12 can be made from either of the surfaces of the substrate 10 regardless of the side of the substrate 10 on which the wiring patterns 12 are formed.

As shown in FIG. 1, the substrate 10 in accordance with the present exemplary embodiment may have lands 16 on a surface opposite to a surface where a semiconductor chip 20 is mounted. In other words, the lands 16 may be formed on a surface of the substrate 10 on which the semiconductor chip 20 is mounted. The lands 16 may be formed in an end section, avoiding a center section of the substrate 10. In other words, the lands 16 may be formed in a region that avoids regions where semiconductor chips are mounted. The wiring patterns 12 and the lands 16 may be electrically connected to one another. In the example shown in FIG. 1, through holes 18 are formed in the substrate 10, and the wiring patterns 12 and the lands 16 are electrically connected through the through holes 18.

Next, a plurality of semiconductor chips 20, 30 and 40 are mounted on the substrate 10. Any two of the semiconductor chips stacked in lower and upper layers may be referred to as a first semiconductor chip 20 and a second semiconductor chip 30. Further, the number of semiconductor chips to be mounted is not particularly limited.

The first semiconductor chip 20 may be mounted on the substrate 10. The first semiconductor chip 20 may be, for example, a flash memory, SRAM, DRAM, ASIC or MPU. The first semiconductor chip 20 may in many cases have a rectangular (square or oblong) plane configuration.

A plurality of electrodes 22 are formed on one of the surfaces (the active surface) of the first semiconductor chip 20. The electrodes 22 may be formed thin and flat with aluminum or copper, for example, on the first semiconductor chip 20. The configuration of each of the electrodes 22 in plan view may be rectangular or circular, but is not limited to any shape. Alternatively, bumps may be formed on pads to serve as the electrodes 22. In this case, the bumps may be formed through electroless plating, or may be ball bumps that are formed through wire-bonding. Also, a nickel, chrome or titanium layer may be added between the pads and the bumps as a layer to prevent diffusion of bump metal. The electrodes 22 may be arranged along at least one side (two parallel sides or four sides in many cases) of the active surface of the first semiconductor chip 20. Also, the electrodes 22 may be formed in end sections, avoiding a center section of the active surface of the first semiconductor chip 20.

A passivation film 24 may be formed on the active surface of the first semiconductor chip 20, while avoiding a part of the electrodes 22. The passivation film 24 may be formed with SiO₂, SiN, polyimide resin or the like, for example. Furthermore, a dielectric layer 26 may be formed on the surface of the passivation film 24 and side surfaces of the semiconductor chip.

The first semiconductor chip 20 may be face-up bonded to the substrate 10. In this instance, an adhesive 28 may be used to affix the semiconductor chip 20 to the substrate 10. For example, the adhesive 28 may be placed on the substrate 10, then the semiconductor chip 20 may be face-up bonded, and then a treatment (heat treatment or the like) may be conducted to cause the adhesive 28 to gain its adhesive force, thereby affixing the semiconductor chip 20 to the substrate. The adhesive 28 may be dielectric. Also, the adhesive 28 may be in the form of paste or film. The property and state of the adhesive 28 are not particularly limited.

The semiconductor device in accordance with the present exemplary embodiment may be a so-called stacked type semiconductor device that is formed by stacking a plurality of semiconductor chips 20, 30 and 40 on the substrate 10. In other words, other semiconductor chips may be mounted on the first semiconductor chip 20. As shown in FIG. 1, a second semiconductor chip 30 may be mounted on the first semiconductor chip 20, and further a semiconductor chip 40 may be mounted on the second semiconductor chip 30. In this case, the number of semiconductor chips that are stacked in layers is not particularly limited. Alternatively, a plurality of semiconductor chips 20, 30 and 40 may be stacked in layers in advance, and they may be mounted on the substrate 10. The semiconductor chips 30 and 40 may be affixed by the adhesive 28 described above.

The semiconductor chips 30 and 40 may have the same configuration as that of the first semiconductor chip 20 with respect to their shapes and placement of electrodes. In other words, the semiconductor chips 30 and 40 may have a plurality of electrodes 32 and 42, respectively. Also, passivation films 34 and 44 may be formed on their active surfaces, and dielectric layers 36 and 46 may be formed on surfaces of the passivation films 34 and 44 and side surfaces of the semiconductor chips 30 and 40, respectively. Further, contents of the plurality of semiconductor chips 30 and 40 may be similar to those of the first semiconductor chip 20, and their combinations can be those with an ASIC, a flash memory and an SRAM, SRAMs alone, DRAMs alone, or a flash memory and SRAMs, for example.

As indicated in FIG. 1, in the method of manufacturing a semiconductor device in accordance with the present exemplary embodiment, all of the semiconductor chips 20, 30 and 40 that are to be stacked may be face-up bonded. In this instance, the second semiconductor chip 30 may be smaller than the first semiconductor chip 20, but they are not limited to this.

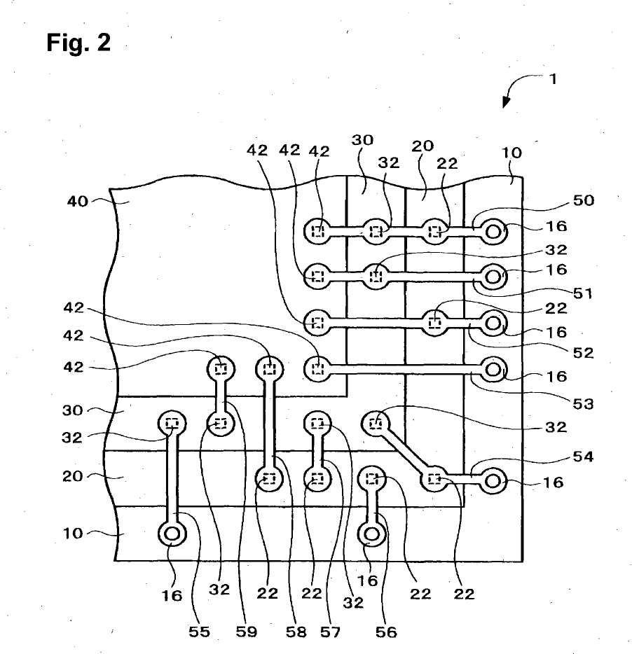

Next, conductive layers that electrically connect the electrodes of the semiconductor chips and the lands 16 are formed to pass side surfaces of the semiconductor chips. More specifically, as shown in FIG. 2, a conductive layer 50 that electrically connects all of the electrodes 22, 32 and 42 to the land 16 may be formed to pass surfaces of the dielectric layers 26, 36 and 46. Alternatively, a conductive layer 51 that electrically connects the electrodes 32 and 42 to the land 16 may be formed to pass a side surface of the dielectric layer 26. Alternatively, a conductive layer 52 that electrically connects the electrodes 22 and 42 to the land 16 may be formed to pass surfaces of the dielectric layers 26, 36 and 46. Alternatively, a conductive layer 53 that electrically connects the electrode 42 to the land 16 may be formed to pass surfaces of the dielectric layers 26, 36 and 46. Alternatively, a conductive layer 54 that electrically connects the electrodes 22 and 32 to the land 16 may be formed to pass surfaces of the dielectric layers 26 and 36. Alternatively, a conductive layer 55 that electrically connects the electrode 32 to the land 16 may be formed to pass surfaces of the dielectric layers 26 and 36. Alternatively, a conductive layer 56 that electrically connects the electrode 22 to the land 16 may be formed to pass a surface of the dielectric layer 26.

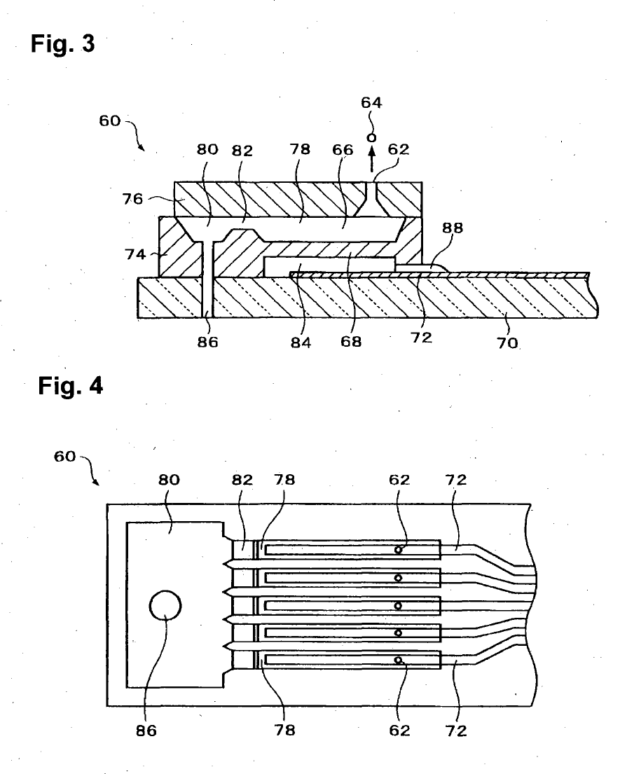

The conductive layers 50-56 may be formed by ejecting a solution containing fine-particles of conductive material. For example, an ink jet method may be used to eject droplets of solution containing fine particles of conductive material to thereby form the conductive layers 50-56. More specifically, an ink jet head 60 shown in FIGS. 3 and 4 is used to eject droplets of solution containing fine particles of conductive material that shows substantially the same behavior as a liquid to thereby form the conductive layers 50-56. Here, “Perfect Gold” or “Perfect Silver” manufactured by Vacuum Metallurgy Corp. may be used as the solution containing fine particles of conductive material.

The ink jet head 60 shown in FIGS. 3 and 4 has an electrostatic actuator structure, e.g., an actuator with a micro-structure that is formed by using a fine-processing technique by a micro-machining technology. The actuator with such a micro-structure uses electrostatic force as its driving source. The ink jet head 60 ejects droplets 64 through a nozzle 62 by using electrostatic force. FIG. 3 is a schematic showing a cross-section of the ink jet head 60, and FIG. 4 is a plan view describing an internal structure of the ink jet head 60.

More specifically, a bottom surface of an ink flow path 66 that connects to the nozzle 62 is formed as a vibration plate 68 that works as a flexible deformable oscillator. A glass substrate 70 is disposed opposite to the vibration plate 68 at a specified separation, and wiring patterns 72 are formed on the glass substrate 70. When a voltage is applied to the wiring patterns 72, electrostatic force is generated between the wiring patterns 72 and the vibration plate 68, such that the vibration plate 68 is vibrated and electrostatically attracted toward the glass substrate 70. By the vibrations of the vibration plate 68, an inner pressure of the ink flow path 66 changes such that droplets 64 are ejected from the nozzles 62.

The ink jet head 60 has a three-layer structure in which a silicon substrate 74 having the ink flow path 66 formed therein is sandwiched between a nozzle plate 76 made of silicon disposed on the upper side, and the glass substrate 70 made of borosilicate glass disposed on the lower side.

A plurality of independent ink chambers 78, a common ink chamber 80 that connects to each of the ink chambers 78, and ink supply paths 82 that connect the ink chambers 78 and the common ink chamber 80 are formed as grooves by an etching method in the silicon substrate 74 that is disposed in the center of the three-layer structure. These grooves are closed by the nozzle plate 76 such that each of the sections is defined. Also, a vibration chamber 84 is independently formed in each of the ink chambers 78 by an etching method in a surface of the silicon substrate 74 opposite to the surface where these grooves are formed.

The common ink chamber 80 is provided with an ink supply port 86 to supply a solution containing fine particles of conductive material from an ink tank not shown in the drawing.

Nozzles 62 are formed in the nozzle plate 76 at positions corresponding to the respective ink chambers 78, and the nozzles 62 communicate with the respective ink chambers 78. Droplets 64 are ejected from the respective nozzles 62 by the vibration chambers 84 formed at the respective ink chambers 78.

A sealing section 88 provided is to seal a gap formed between the wiring patterns 72 on the glass substrate 70 and the silicon substrate 74.

The aforementioned ink jet head 60 may be used to eject the solution containing fine particles of conductive material as droplets 64 to thereby form the conductive layer 50. For example, the ink jet head 60 may be adjusted such that the droplets 64 are ejected vertically with respect to the dielectric layers 26, 36 and 46, to thereby form the conductive layer 50 on the surfaces of the dielectric layers 26, 36 and 46. In this case, the ink jet head 60 may be re-adjusted such that the droplets 64 are ejected vertically with respect to the semiconductor chips 20, 30 and 40, to thereby form the conductive layer 50 on the surfaces of the semiconductor chips 20, 30 and 40. Besides this, the ink jet head 60 may be adjusted such that the droplets 64 are ejected diagonally with respect to the semiconductor chips 20, 30 and 40, to thereby form the conductive layer 50.

The structure of the ink jet head 60 described above is an example, and is not limited to this example. Also, a mechanism that ejects the solution containing fine particles of conductive material is not limited to an ink jet head.

Similarly, a second conductive layer that electrically connect the plurality of electrodes 22, 32 and 42 may be formed to pass side surfaces of the semiconductor chips. More specifically, as indicated in FIG. 2, a second conductive layer 57 that electrically connects the electrode 22 and the electrode 32 may be formed to pass a surface of the dielectric layer 36. Alternatively, a second conductive layer 58 that electrically connects the electrode 22 and the electrode 42 may be formed to pass surfaces of the dielectric layers 36 and 46. Alternatively, a second conductive layer 59 that electrically connects the electrode 32 and the electrode 42 may be formed to pass a surface of the dielectric layer 46.

Next, external terminals 14 are formed on the substrate 10. In the example shown in FIG. 1, the external terminals 14 are formed on the wiring patterns 12, and electrically connected to the lands 16 through the wiring patterns 12 (and the through holes 18). As the external terminals 14, solder balls or the like may be used. As indicated in FIG. 1, the external terminals 14 may be formed in a mounting region of the semiconductor chip 20 to provide a Fan—In type. Alternatively, the external terminals 14 may be provided only in an area outside of the mounting region of the semiconductor chip 20 to provide a Fan—Out type. Further, the external terminals 14 may be formed inside and outside of the mounting region of the semiconductor chip 20 to provide a Fan—In/Out type.

By the steps described above, the semiconductor device 1 can be manufactured. However, the method of manufacturing the semiconductor device 1 is not limited to this example. For example, a semiconductor device may be fabricated by mounting only the first semiconductor chip 20 on the substrate 10. Alternatively, a semiconductor device may be fabricated without forming the second conductive layers 57-59.

As shown in FIGS. 1 and 2, the conductive layers 50-56 or the second conductive layers 57-59, in accordance with the present exemplary embodiment, are formed on surfaces of the dielectric layers 26, 36 and 46. By this, the conductive layers 50-56 and/or the second conductive layers 57-59 are formed to pass side surfaces of the semiconductor chips 20, 30 and 40, such that the semiconductor device does not become large. Also, a solution containing fine-particles of conductive material is ejected to form the conductive layers 50-56 and/or the second conductive layers 57-59, such that these wirings can be miniaturized and therefore small semiconductor devices can be manufactured.

The semiconductor device 1 thus formed by the aforementioned steps has the substrate 10 that includes the wiring patterns 12. The semiconductor device 1 has the electrodes 22, 32 and 42, and the multiple semiconductor chips 20, 30 and 40 that are stacked one on top of the other. The stacked semiconductor chips 20, 30 and 40 are mounted on the substrate 10. Also, the semiconductor device 1 has the conductive layers 50-56 that are formed to pass side surfaces of the semiconductor chips 20, 30 and 40. Further, the semiconductor device 1 has the second conductive layers 57-59.

(Second Exemplary Embodiment)

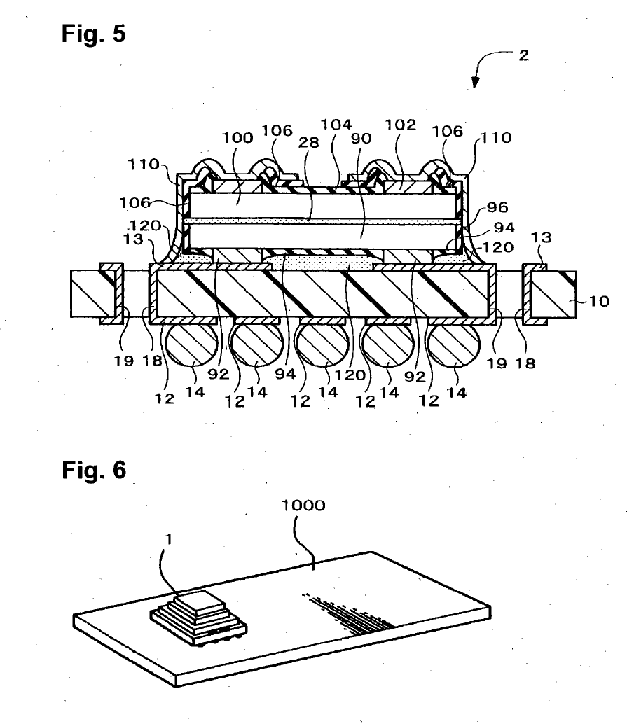

FIG. 5 is a schematic describing a method of manufacturing a semiconductor device in accordance with a second exemplary embodiment of the present invention. The contents described in the first exemplary embodiment can be applied as much as possible to the present exemplary embodiment.

Initially, a substrate 10 is prepared. As shown in FIG. 5, the substrate 10 in accordance with the present exemplary embodiment may have wiring patterns formed on both surfaces thereof. In other words, wiring patterns 13 may be formed on a side of the substrate 10 on which a semiconductor chip is mounted. Wiring patterns 12 and the wiring patterns 13 may be electrically connected to one another. In the example shown in FIG. 5, they are electrically connected by through holes 18.

Next, a first semiconductor chip 90 and a second semiconductor chip 100 are mounted on the substrate 10. Here, the first semiconductor chip 90 and the second semiconductor chip 100 may have the same configuration as that of the first semiconductor chip 20 with respect to their shapes and placement of electrodes. In other words, the semiconductor chips 100 and 100 may have a plurality of electrodes 92 and 102, respectively. Also, passivation films 94 and 104 may be formed on their active surfaces, and dielectric layers 96 and 106 may be formed on surfaces of the passivation films 94 and 104 and side surfaces of the semiconductor chips 90 and 100, respectively. Further, contents of the plurality of semiconductor chips 90 and 100 may be similar to those of the first semiconductor chip 20, and their combinations can be those with an ASIC, a flash memory or an SRAM, SRAMs alone, DRAMs alone, or a flash memory and an SRAM, for example.

The first semiconductor chip 90 may be mounted on the substrate 10. The first semiconductor chip 90 is face-down bonded to the substrate 10, and the wiring patterns 13 and electrodes 92 may be electrically connected to one another. The first semiconductor chip 90 may be affixed to the substrate 10 by an adhesive 120. In the present exemplary embodiment, anisotropic conductive material may be used as the adhesive 120. In other words, the wiring patterns 13 and the electrodes 92 may be electrically connected by conductive particles (not shown) that are included in the anisotropic conductive material. The adhesive 120 may be provided as an anisotropic conductive film in the form of a sheet, or as anisotropic conductive paste in the form of paste. A thermosetting resin (for example, an epoxy resin) may be used as a binder of the adhesive 120. Besides this, the aforementioned adhesive 28 may be used to affix the first semiconductor chip 90 to the substrate 10.

Next, the second semiconductor chip 100 may be mounted on the first semiconductor chip 90. The second semiconductor chip 100 may be face-up bonded to the first semiconductor chip 90. More specifically, the second semiconductor chip 100 may be face-up bonded to a surface of the first semiconductor chip 90 opposite to the surface thereof where the electrodes 92 are formed. The second semiconductor chip 100 may be affixed to the first semiconductor chip 90 by using the aforementioned adhesive 28.

The method of stacking the semiconductor chips is not limited to the above. For example, the second semiconductor chip 100 is face-up bonded to the first semiconductor chip 90 in advance, and they can be mounted on the substrate 10.

Next, conductive layers 110 that electrically connect the electrodes 102 and the wiring patterns 13 are formed. The conductive layers 110 may be formed to pass side surfaces of the first semiconductor chip 90 and the second semiconductor chip 100. In other words, the conductive layers 110 may be formed on surfaces of the dielectric layers 96 and 106. Alternatively, the conductive layers 110 may be formed on surfaces of the adhesive 120. The conductive layers 110 can be formed by the method described above in the first embodiment.

By the steps described above, the semiconductor device 2 can be manufactured. However, the method of manufacturing the semiconductor device 2 is not limited to this example.

As shown in FIG. 5, the conductive layers 110 in accordance with the present exemplary embodiment are formed on surfaces of the dielectric layers 96 and 106, or surfaces of the adhesive 120. By this, the conductive layers 110 are formed to pass side surfaces of the semiconductor chips 90 and 100 such that the semiconductor device does not become large. Also, a solution containing fine particles of conductive material is ejected to form the conductive layers 110, such that these wirings can be miniaturized and therefore small semiconductor devices can be manufactured.

The semiconductor device 2 thus manufactured by the steps described above has the substrate 10 having the wiring patterns 12 and 13. The semiconductor device 2 has the first semiconductor chip 90 that has the electrodes 92 and is face-down bonded to the substrate 10. The semiconductor device 2 has the second semiconductor chip 100 that has the electrodes 102 and is face-up bonded to a side of the first semiconductor chip 90 opposite to the side thereof where the electrodes 92 are formed. Also, the semiconductor device 2 has the conductive layers 110 that are formed to pass side surfaces of at least the first semiconductor chip 90.

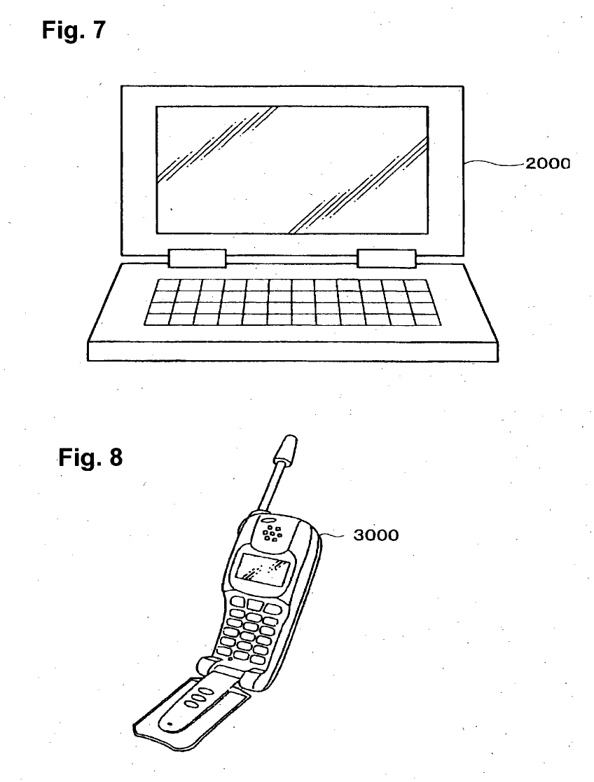

FIG. 6 shows a circuit substrate 1000 on which the semiconductor device 1 in accordance with the exemplary embodiment described above is mounted. Also, as exemplary electronic apparatuses having the semiconductor devices in accordance with the exemplary embodiment of the present invention, a notebook type personal computer 2000 is shown in FIG. 7, and a portable telephone 3000 is shown in FIG. 8.

The present invention is not limited to the exemplary embodiments described above, and many modification can be made. For example, the present invention may include compositions that are substantially the same as the compositions described in the exemplary embodiments (for example, a composition that has the same functions, the same methods and the results, or a composition that has the same objects and results). Also, the present invention includes compositions in which portions not essential in the compositions described in the exemplary embodiments are replaced with others. Also, the present invention includes compositions that achieve the same functions and effects or achieve the same objects of those of the compositions described in the exemplary embodiments. Furthermore, the present invention includes compositions that include related art, later developed or publicly known technology added to the compositions described in the exemplary embodiments.

What is claimed is:

1. A method of manufacturing a semiconductor device, comprising:
mounting a semiconductor chip having electrodes on a substrate having wiring patterns; and
forming conductive layers that electrically connect the electrodes and the wiring patterns in a manner to pass side surfaces of the semiconductor chip.

2. The method of manufacturing a semiconductor device according to claim 1, further including face-up bonding the semiconductor chip.

3. A method of manufacturing a semiconductor device, comprising:
stacking in layers a plurality of semiconductor chips having electrodes on a substrate having wiring patterns; and
forming a conductive layer that electrically connects the electrodes of any one of the semiconductor chips and the wiring patterns in a manner to pass a side surface of at least one of the semiconductor chips.

4. The method of manufacturing a semiconductor device according to claim 3, further including face-up bonding the plurality of semiconductor chips.

5. The method of manufacturing a semiconductor device according to claim 3, further including mounting a second semiconductor chip, that is smaller than a first semiconductor chip among the plurality of semiconductor chips, on the first semiconductor chip.

6. The method of manufacturing a semiconductor device according to claim 3, further including forming a second conductive layer that electrically connects the electrodes of one of the semiconductor chips and the electrodes of another of the semiconductor chips in a manner to pass a side surface of at least one of the semiconductor chips.

7. The method of manufacturing a semiconductor device according to claim 3, further including face-down bonding a first semiconductor chip among the plurality of semiconductor chips to the substrate, and face-up bonding a second semiconductor chip to a side of the first semiconductor chip opposite to a side where the electrodes are formed.

8. The method of manufacturing a semiconductor device according to claim 1, further including forming the conductive layer by ejecting a solution containing fine-particles of conductive material.

9. A semiconductor device, comprising:
a substrate having wiring patterns;
a plurality of stacked semiconductor chips having electrodes;
a conductive layer that electrically connects the electrodes of any one of the semiconductor chips and the wiring patterns in a manner to pass a side surface of at least one of the semiconductor chips; and
a second conductive layer that electrically connects the electrodes of one of the semiconductor chips and the electrodes of another of the semiconductor chips in a manner to pass a side surface of at least one of the semiconductor chips.

10. The semiconductor device according to claim 9, the plurality of semiconductor chips being face-up bonded.

11. The semiconductor device according to claim 10, a second semiconductor chip that is smaller than a first semiconductor chip among the plurality of semiconductor chips being mounted on the first semiconductor chip.

12. The semiconductor device according to claim 9, a first semiconductor chip among the plurality of semiconductor chips being face-down bonded to the substrate, and a second semiconductor chip being face-up bonded to a side of the first semiconductor chip opposite to a side thereof where the electrodes are formed.

13. A circuit substrate assembly, comprising:
a circuit substrate; and
the semiconductor device according to claim 9 mounted on the circuit substrate.

14. An electronic equipment, comprising:
the semiconductor device according to claim 9.
